(19) United States
(12) Patent Application Publication
(10) Pub. No.: US 2020/0309840 A1
(43) Pub. Date: Oct. 1, 2020

(54) Error Detection Wiring Circuit and Switching Device for Instrument Transformers in Distribution Power Grid

(71) Applicant: Dake He, Auburn, AL (US)

(72) Inventors: Dake He, Aubum, AL (US); Kun Liu, Chengdu (CN); Gang Liu, Chengdu (CN); Bing Ai, Chengdu (CN); Bo Jiang, Chengdu (CN); Jiapeng Huang, Chengdu (CN); Na He, Chengdu (CN); Wei Jiang, Chengdu (CN); Qiang Shi, Chengdu (CN)

(73) Assignees: Dake He, Auburn, AL (US); Kun Liu, Chengdu (CN); Gang Liu, Chengdu (CN)

(21) Appl. No.: 16/371,137

(22) Filed: Apr. 1, 2019

(51) Int. Cl. G01R 31/02; G01R 15/18

(52) U.S. Cl. CPC G01R 31/027; G01R 15/18

(57) ABSTRACT

The invention discloses an error detection wiring circuit and switching device for instrument transformers in distribution power grid, wherein the wiring circuit integrates a three-phase three-wire metering circuit and a three-phase four-wire metering circuit, and the switching device comprises a linear push rod and a driving motor. Through the control of the driving motor, the movement of the linear push rod to the through terminal ports, which consist of the BN terminal, the CN terminal, and the P1B terminal, is realized. With this, the conversion of the two methods can be realized by simply switching the short circuit wiring of the P1B terminal or the BN terminal to the CN terminal and the AN terminal. Using certain measurement method, each phase of the transformer to be tested can be measured simultaneously, which improves the accuracy of the detected data. Meanwhile, the prior art of wiring conduction structure is changed into a rod-shaped jack-type conduction structure, such that the two-step wiring procedure is reduced to one step during measurement, which can be realized by simply controlling the forward and reverse rotation of the driving motor. No manual wiring operation is required, which is safer and more convenient, and greatly improves the efficiency of wiring conversion during measurement.

### BACKGROUND

The 10 kV distribution power grid has the characteristics of wide distribution and great influence. There are a large number of instrument transformers in the 10 kV distribution power grid, and the primary system is divided into three-phase three-wire and three-phase four-wire wiring system according to whether the neutral point is grounded. Correspondingly, the metering methods used by the instrument transformers are also divided into three-phase three-wire metering method and three-phase four-wire metering method, where the instrument transformers usually contain two current transformers and two voltage transformers in three-phase three-wire metering method, and the instrument transformer usually contain three current transformers and three voltage transformers in three-phase four-wire metering method. Research shows that the true metering performance of the instrument transformers can be detected more accurately by simulating the operating states of the instrument transformers under the actual working conditions. That is, three-phase detection method should be used to detect the metering performance of instrument transformers, and voltage and current should be simultaneously applied to each phase of the voltage and current instrument transformers, and the error of the current or the voltage transformer is detected under this condition.

### DETAILED DESCRIPTION OF THE INVENTION

The purpose of this invention is to provide a transformer error detecting wiring circuit and a switching device, which can achieve the goal of conveniently, quickly and safely switching wirings of metering performance detection of instrument transformers under two metering methods (The switch will be at a high voltage of 5.77 kV under three-phase three-wire wiring method).

The invention is achieved by the following technical solutions:

A transformer error detection wiring circuit, including a transformer to be tested, and also including A, B, C three-phase standard voltage transformers and A, B, C three-phase boosters, is characterized in that: one end of the said A-phase standard voltage transformer is connected to the P1A terminal, and another end is connected to the AN terminal; One end of the said B-phase standard voltage transformer is connected to the P1B terminal, and another end is connected to the BN terminal; One end of the said C phase standard voltage transformer is connected to the P1B terminal, and another end is connected to the CN terminal; P1A, P1B, and P1C are the high-voltage-end terminals of the primary side of the A, B, and C phase of the boosters, respectively, and the AN, BN, and CN are the low-voltage-end terminals of the primary side of the A, B, and C phase of the boosters, respectively; The said AN terminal is short-circuited with the CN terminal, the BN terminal is grounded, and the P1A, P1B, and P1C terminals are connected to the transformer to be tested respectively, where:

When the P1B terminal is connected to the short wiring of the CN terminal and the AN terminal, the error detection for an instrument transformer in distribution power grid with three-phase three-wire method is performed using the three-phase detection method;

When the BN terminal is connected to the short wiring of the CN terminal and the AN terminal, the error detection for an instrument transformer in distribution power grid with three-phase four-wire method is performed using the three-phase detection method.

Further, currently, whether the three-phase three-wire metering method or the three-phase four-wire metering method is adopted, the existing detecting method and the detecting device detect only one phase of the transformer to be tested at one time. This makes the final measured data cannot truly reflect the metering performance of the tested transformer. Therefore, three-phase detection method is required. In order to improve the adaptability of the device with the three-phase detection method, and to be adapt to the transformers in the distribution power grid with different metering methods, the invention innovatively designs a circuit conversion structure that integrates three-phase three-wire metering method and three-phase four-wire metering method. The specific structure is as described above. Since the AN terminal is short-circuited to the CN terminal, the BN terminal is grounded, and the P1B terminal is directly connected to the B-phase booster, which is at a high potential. Therefore, when the short wiring of the P1B terminal is conducted with the CN terminal and the AN terminal, the AN and CN terminals are also at high voltage potential, and the error detection for an instrument transformer in distribution power grid with three-phase three-wire method is performed using the three-phase detection method. When the short wiring of the BN terminal is conducted with the CN terminal and the AN terminal, the AN and CN terminals are at a low voltage potential at this time, and the error detection for an instrument transformer in distribution power grid with three-phase four-wire method is performed using the three-phase detection method. Through the above circuit conversion structure, this invention can realize the conversion between two modes simply by switching the short connection of the P1B terminal or the BN terminal with the CN terminal and the AN terminal, and can simultaneously measure each phase of the transformer to be tested by mimicking the actual working conditions of an instrument transformer in distribution power grid, which improves the accuracy of the detected data.

Further, it also includes A, B, C three-phase current boosters, and A, B, C three-phase standard current transformers. The said input terminal of P1A is also connected to the A-phase booster and phase A of the transformer to be tested, respectively, and its output terminal is connected to phase A of the transformer to be tested through the A-phase current booster and the A-phase standard current transformer in sequence; The said input terminal of P1B is also connected to the B-phase booster and phase B of the transformer to be tested, respectively, and its output terminal is connected to phase B of the transformer to be tested through the B-phase booster and the B-phase standard current transformer in sequence; The said input terminal of P1C is also connected to the C-phase booster and phase C of the transformer to be tested, respectively, and its output terminal is connected to the phase C of the transformer to be tested through the C-phase current transformer and the C-phase standard current transformer.

Further, the said transformer to be tested comprises three voltage transformers to be tested and one current transformer to be tested; The input terminals of the three voltage transformers to be tested and the current transformer to be tested are SP1A, SP1B, SP1C, respectively, and the output terminals are SP2A, SP2B, SP2C, respectively. The said input terminals of P1A, P1B, and P1C are connected with SP1A, SP1B, and SP1C respectively, and the output terminals are connected with SP2A, SP2B, and SP2C respectively.

The switching device based on the transformer error detecting wiring circuit includes a lead wire terminal. The said lead wire terminal includes a BN terminal, a CN terminal, and a P1B terminal, wherein the said BN, CN and the P1B terminals are sequentially disposed, and the center point connections of the terminal ports of the three terminals are in the same straight line. A changeover switch is also included, which includes a linear push rod and a driving motor, and the axis of the said linear push rod is parallel to the said straight line, wherein the linear push rod includes an upper section, a middle section, and a lower section. The said upper section is a metal conductor, the middle section and the lower section are both insulators, and the end of the lower section is connected to the output shaft of the drive motor, where:

When the driving motor rotates forward, the said linear push rod approaches its P1B terminal along its axial direction. When the upper section of the linear push rod is in contact with the CN terminal and the P1B terminal simultaneously, the error detection for the instrument transformer in distribution power grid with three-phase three-wire method is performed using the three-phase detection method.

When the drive motor rotates reverse, the said linear push rod moves toward the BN terminal along its axial direction. When the upper section of the linear push rod is in contact with the BN terminal and the CN terminal simultaneously, the error detection for the instrument transformer in distribution power grid with three-phase four-wire method is performed using the three-phase detection method. Further, in order to realize the conversion between measurement modes of the three-phase three-wire mode and the three-phase four-wire mode conveniently, quickly and safely, this invention integrates the transformer error detection wiring circuit described above into a switching device, including the lead wire terminals. First, the BN terminal, the CN terminal, and the P1B terminal are sequentially arranged and formed into a straight line, and then a corresponding changeover switch is designed. The changeover switch comprises a linear push rod and a driving motor, and the metal conductor part of the linear push rod is in contact with the terminal port to achieve conduction of the measuring circuit. The lower section of the linear push rod is made of insulation material, and is connected to the driving motor. The movement of the linear push rod to the BN terminal, the CN terminal, and the P1B terminal is controlled by the driving motor. In this way, the two metering methods can be switched easily by merely pushing the driving motor such that the metal conductor part of the linear push rod is in contact with the corresponding BN terminal and CN terminal, or CN terminal and P1B terminal. By using above approach, the prior art of wiring conduction structure is changed into a rod-shaped jack-type conduction structure, such that the two-step wiring procedure is reduced to one step during measurement, which can be realized by simply controlling the forward and reverse rotation of the driving motor. No manual wiring operation is required, which is safer and more convenient, and greatly improves the efficiency of wiring conversion during measurement.

The connection of the said upper section, the middle section and the lower section is dismantlable. Further, since the connection of the upper section, the middle section and the lower section of the linear push rod is dismantlable, each section can be conveniently replaced or repaired when this section is damaged, thereby saving the cost of raw materials and manufacturing the linear push rod, and being more economical and environmentally friendly, and being very practical.

Preferably, the upper section, the middle section and the lower section are connected by a buckle. A buckle is very convenient to install and disassemble, and the structure is relatively stable when locked, and the structure is simple and convenient for processing, which is very suitable for this invention.

Radial insulation stripes are engraved on the wall of the said middle section. Further, by designing the radial insulation stripes on the middle section, the insulation distance of the section can be increases, and the insulation distance requirement for 10 kV voltage level is insured to be satisfied.

Preferably, the said radial insulation stripes are wavy or sawtooth.

Preferably, a wireless communication module and a control chip are further installed on the driving motor, and the driving motor and the wireless communication module are respectively connected to the control chip, wherein:

The said wireless communication module is configured to receive wireless driving signals and transmit the wireless driving signals to the control chip;

The said control chip is used to receive the wireless driving signals transmitted by the wireless communication module, and to send forward driving signals or reverse driving signals to the driving motor;

The said driving motor is used to receive forward rotation driving signals or reverse driving signals sent by the control chip, and to control the driving motor to rotate forward or reverse. The driving motor of the prior art is generally wired to the control module. The invention provides a way of wirelessly controlling the forward and reverse rotation of the driving motor. By installing a wireless communication module and a control chip on the driving motor, the measuring personnel can control the forward rotation and reverse rotation of the driving motor distantly. This approach makes the measurement safer, more user-friendly and more intelligent.

Comparing with the prior art, this invention has the following advantages and benefits:

1. This invention relates to a transformer error detecting wiring circuit and a switching device, which is an innovative design of a circuit structure that integrates a three-phase three-wire metering circuit and a three-phase four-wire metering circuit, as well as corresponding switching device. The switching device includes a linear push rod and a driving motor. Through the control of the driving motor, the movement of the linear push rod to the through terminal ports, which is formed by the BN terminal, the CN terminal, and the P1B terminal, is realized. With this, the conversion of the two methods can be realized by simply switching the short circuit wiring of the P1B terminal or the BN terminal to the CN terminal and the AN terminal. Using certain measurement method, each phase of the transformer to be tested can be measured simultaneously, which improves the accuracy of the detected data. Meanwhile, the prior art of wiring conduction structure is changed into a rod-shaped jack-type conduction structure, such that the two-step wiring procedure is reduced to one step during measurement, which can be realized by simply controlling the forward and reverse rotation of the driving motor. No manual wiring operation is required, which is safer and more convenient, and greatly improves the efficiency of wiring conversion during measurement.

2. This invention relates to a transformer error detecting wiring circuit and a switching device, and the connection of the upper section, the middle section and the lower section of the linear push rod is dismantlable. Each section can be conveniently replaced or repaired when this section is damaged, thereby saving the cost of raw materials and manufacturing the linear push rod, and being more economical and environmentally friendly, and being very practical;

3. This invention relates to a transformer error detecting wiring circuit and a switching device. By installing a wireless communication module and a control chip on the driving motor, the measuring personnel can control the forward rotation and reverse rotation of the driving motor distantly. This approach makes the measurement safer, more user-friendly and more intelligent.

### BRIEF DESCRIPTION OF THE DRAWINGS

The drawings illustrated herein are intended to provide a further understanding of the embodiments of the invention, form part of this application, and do not constitute a limitation of the embodiments of the invention. In the drawings:

FIG. 1 is the wiring circuit diagram of a three-phase three-wire method for error detection of a transformer in this invention;

FIG. 2 is the wiring circuit diagram of the three-phase four-wire method for error detection of a transformer in this invention;

FIG. 3 is the schematic view showing the arrangement of the terminals of the lead wires in this invention;

FIG. 4 is the schematic structural view of the changeover switch in a three-phase three-wire mod in this invention;

FIG. 5 is the schematic structural view of the changeover switch in a three-phase four-wire mode in this invention;

FIG. 6 is the schematic diagram of wireless driving control of the driving motor in this invention.

### MARKS AND CORRESPONDING PART NAMES IN THE DRAWING

2—Upper Section, 3—Middle Section, 4—Lower Section, 5—BN Terminal, 6—CN Terminal, 7—P1B Terminal, 8—Driving Motor.

### DETAILED IMPLEMENTATION METHODS

In order to further clarify the objects, technical solutions and advantages of the present invention, the present invention will be further described in details below with reference to the embodiments and the accompanying drawings. The illustrative embodiments of the present invention and the description thereof are merely illustrative of the invention and are not intended to limit the invention.

### Implementing Example 1

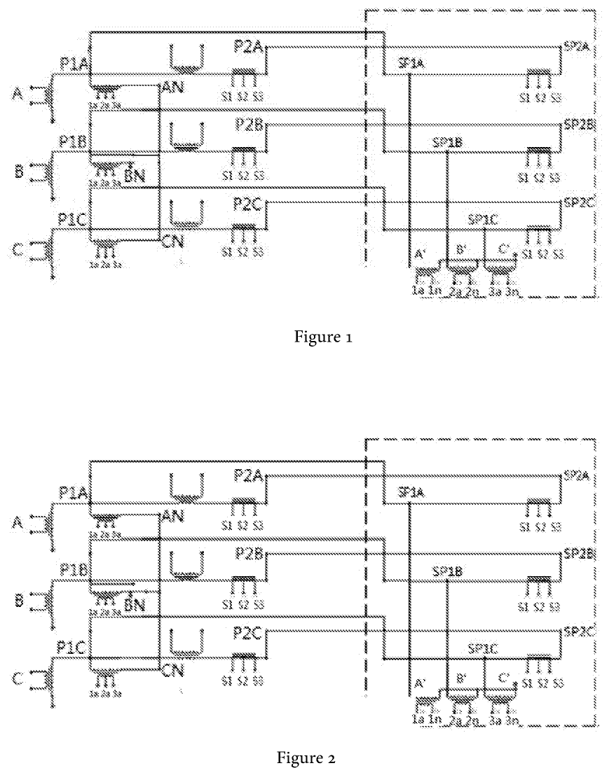

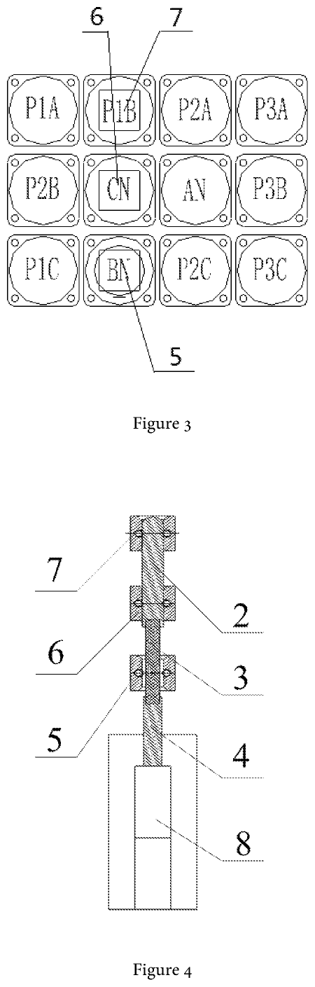

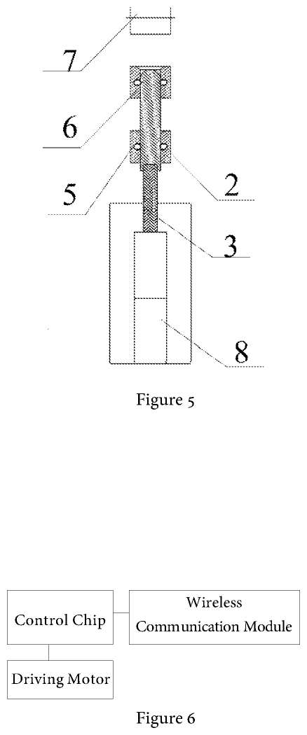

As shown in FIG. 1˜2, this invention relates to a transformer error detection wiring circuit, including a transformer to be tested, and also including A, B, C three-phase standard voltage transformers and A, B, C three-phase boosters. One end of the said A-phase standard voltage transformer is connected to the P1A terminal, and another end is connected to the AN terminal; One end of the said B-phase standard voltage transformer is connected to the P1B terminal, and another end is connected to the BN terminal; One end of the said C phase standard voltage transformer is connected to the P1B terminal, and another end is connected to the CN terminal; P1A, P1B, and P1C are the high-voltage-end terminals of the primary side of the A, B, and C phase of the boosters, respectively, and the AN, BN, and CN are the low-voltage-end terminals of the primary side of the A, B, and C phase of the boosters, respectively; The said AN terminal is short-circuited with the CN terminal, the BN terminal is grounded, and the P1A, P1B, and P1C terminals are connected to the transformer to be tested respectively, where:

When the P1B terminal is connected to the short wiring of the CN terminal and the AN terminal, the error detection for an instrument transformer in distribution power grid with three-phase three-wire method is performed using the three-phase detection method;

When the BN terminal is connected to the short wiring of the CN terminal and the AN terminal, the error detection for an instrument transformer in distribution power grid with three-phase four-wire method is performed using the three-phase detection method. It also includes A, B, C three-phase current boosters, and A, B, C three-phase standard current transformers. The said input terminal of P1A is also connected to the A-phase booster and phase A of the transformer to be tested, respectively, and its output terminal is connected to phase A of the transformer to be tested through the A-phase current booster and the A-phase standard current transformer in sequence; The said input terminal of P1B is also connected to the B-phase booster and phase B of the transformer to be tested, respectively, and its output terminal is connected to phase B of the transformer to be tested through the B-phase booster and the B-phase standard current transformer in sequence; The said input terminal of P1C is also connected to the C-phase booster and phase C of the transformer to be tested, respectively, and its output terminal is connected to the phase C of the transformer to be tested through the C-phase current transformer and the C-phase standard current transformer. The said transformers to be tested comprise three voltage transformers to be tested and one current transformer to be tested; The input terminals of the three voltage transformers to be tested and the current transformer to be tested are SP1A, SP1B, SP1C, respectively, and the output terminals are SP2A, SP2B, SP2C, respectively. The said input terminals of P1A, P1B, and P1C are connected with SP1A, SP1B, and SP1C respectively, and the output terminals are connected with SP2A, SP2B, and SP2C respectively. In the Figures, P1A, P2A, and P3A are the A-phase high-voltage-end terminals of the primary side, and AN is the A-phase low-voltage-end terminal of the primary side; P1B, P2B, and P3B are the B-phase high-voltage-end terminals of the primary side, and BN is the B-phase low-voltage-end terminal of the primary side; P1C, P2C, and P3C are the C-phase high-voltage-end terminals of the primary side, and CN is the C-phase low-voltage-end terminal of the primary side. These terminals are extracted fully insulated. Through the above circuit structure, and compared with the prior art, the conversion of the two methods is realized in this invention by simply switching the short circuit wiring of the P1B terminal or the BN terminal to the CN terminal and the AN terminal. Using certain measurement method, each phase of the transformer to be tested can be measured simultaneously, which improves the accuracy of the detected data.

### Implementing Example 2

As illustrated in FIG. 1˜5, in this invention, the switching device based on the transformer error detecting wiring circuit includes a lead wire terminal. The said lead wire terminal includes a BN terminal, a CN terminal, and a P1B terminal, wherein the said BN, CN and the P1B terminals are sequentially disposed, and the center point connection lines of the terminal ports of the three terminals are in the same straight line. The changeover switch is also included, which includes a linear push rod and a driving motor, and the axis of the said linear push rod is parallel to the said straight line, wherein the linear push rod includes an upper section (2), a middle section (3), and a lower section (3). The said upper section (2) is a metal conductor, the middle section (3) and the lower section (4) are both insulators, and the end of the lower section (4) is connected to the output shaft of the drive motor (8), where:

When the driving motor (8) rotates forward, the said linear push rod approaches its P1B terminal (7) along its axial direction. When the upper section (2) of the linear push rod is in contact with the CN terminal (6) and the P1B terminal (7) simultaneously, the error detection for the instrument transformer in distribution power grid with three-phase three-wire method is performed using the three-phase detection method;

When the drive motor (8) rotates reverse, the said linear push rod moves toward the BN terminal (5) along its axial direction; When the upper section (2) of the linear push rod is in contact with the BN terminal (5) and the CN terminal (6) simultaneously, the error detection for the instrument transformer in distribution power grid with three-phase four-wire method is performed using the three-phase detection method. The connections of the said upper section (2), the middle section (3) and the lower section (4) are dismantlable. The said upper section (2), the middle section (3) and the lower section (4) are connected by a buckle. The rod wall of the said middle section (3) is engraved with radial insulation stripes. The said radial insulation stripes are wavy or sawtooth. Through above methods, the existing two-step wiring procedure is reduced to one step during measurement, and the primary wiring can be switched conveniently under different wiring modes when the error detection of a transformer in distribution power grid is performed, which can be realized by simply controlling the forward and reverse rotation of the driving motor (8). No manual wiring operation is required, which is safer and more convenient, and greatly improves the efficiency of wiring conversion during measurement.

### Implementing Example 3

As illustrated in FIG. 6, in the said switching device of this invention based on the transformer error detecting wiring circuit, on the bases of Implementing Example 2, a wireless communication module and a control chip are further installed on the driving motor (8), and the said driving motor (8) and the wireless communication module are respectively connected to the control chip, wherein:

The said wireless communication module is configured to receive wireless driving signals and transmit the wireless driving signals to the control chip;

The said control chip is used to receive the wireless driving signals transmitted by the wireless communication module, and to send forward driving signals or reverse driving signals to the driving motor (8);

The said driving motor (8) is used to receive forward rotation driving signals or reverse driving signals sent by the control chip, and to control the driving motor (8) to rotate forward or reverse. Above structure enables the forward and reverse rotation of the driving motor that can be wirelessly controlled, and makes the measurement safer, more user-friendly and more intelligent.

Above detailed implementing methods further provides detailed explanation of the purpose, technical solutions and beneficial effects of this invention. It should be understood that the above description is only specific embodiments of this invention and is not intended to limit the scope of this invention. Any modifications, equivalent substitutions, improvements, etc., made within the spirit and scope of this invention shall be included in the scope of protection of this invention.

1. An instrument transformer error detection wiring circuit, including a transformer to be tested, and also including A, B, C three-phase standard voltage transformers and A, B, C three-phase boosters, is characterized in that: one end of the said A-phase standard voltage transformer is connected to the P1A terminal, and the other end is connected to the AN terminal; One end of the said B-phase standard voltage transformer is connected to the P1B terminal, and the other end is connected to the BN terminal; One end of the said C-phase standard voltage transformer is connected to the P1B terminal, and the other end is connected to the CN terminal; P1A, P1B, and P1C are the high-voltage-end terminals of the primary side of the A, B, and C-phase of the boosters, respectively, and the AN, BN, and CN are the low-voltage-end terminals of the primary side of the A, B, and C-phase of the boosters, respectively; The said AN terminal is short-circuited with the CN terminal, the BN terminal is grounded, and the P1A, P1B, and P1C terminals are connected to the tested transformer respectively, where:
When the P1B terminal is connected to the short wiring of the CN terminal and the AN terminal, and the error detection for the instrument transformer in distribution power grid with three-phase three-wire method is performed using the three-phase detection method;
When the BN terminal is connected to the short wiring of the CN terminal and the AN terminal, and the error detection for the instrument transformer in distribution power grid with three-phase four-wire method is performed using the three-phase detection method.

2. According to claim 1, the said transformer error detection wiring circuit, including the transformer to be tested, and also including A, B, C three-phase standard voltage transformers and A, B, C three-phase boosters, is characterized in that: The said input terminal of P1A is also connected to the A-phase booster and phase A of the transformer to be tested, respectively, and its output terminal is connected to phase A of the transformer to be tested through the A-phase current booster and the A-phase standard current transformer in sequence; The said input terminal of P1B is also connected to the B-phase booster and phase B of the transformer to be tested, respectively, and its output terminal is connected to phase B of the transformer to be tested through the B-phase current booster and the B-phase standard current transformer in sequence; The said input terminal of P1C is also connected to the C-phase booster and phase C of the transformer to be tested, respectively, and its output terminal is connected to phase C of the transformer to be tested through the C-phase current booster and the C-phase standard current transformer in sequence.

3. According to claim 2, the said transformer error detection wiring circuit is characterized in that: The said transformer to be tested comprises three voltage transformers to be tested and one current transformer to be tested; The input terminals of the three voltage transformers to be tested and the current transformer to be tested are SP1A, SP1B, SP1C, respectively, and the output terminals are SP2A, SP2B, SP2C respectively. The said input terminals of P1A, P1B, and P1C are connected with SP1A, SP1B, and SP1C respectively, and the output terminals are connected with SP2A, SP2B, and SP2C respectively.

4. A switching device based on the transformer error detecting wiring circuit is characterized in including a lead wire terminal. The said lead wire terminal includes a BN terminal, a CN terminal, and a P1B terminal, wherein the said BN, CN and the P1B terminals are sequentially disposed, and the center point connections of the terminal ports of the three terminals are in the same straight line. A changeover switch is also included, which includes a linear push rod and an electric motor, the axis of the said linear push rod being parallel to the said straight line, wherein the linear push rod includes an upper section (2), a middle section (3), and a lower section (4). The said upper section (2) is a metal conductor, the middle section (3) and the lower section (4) are both insulators, and the end of the lower section (4) is connected to the output shaft of the drive motor (8), where:
When the driving motor (8) rotates forward, the said linear push rod approaches its P1B terminal (7) along its axial direction. When the upper section (2) of the linear push rod is in contact with the CN terminal (6) and the P1B terminal (7) simultaneously, the error detection for the instrument transformer in distribution power grid using three-phase three-wire method is performed using the three-phase detection method.
When the drive motor (8) rotates reverse, the said linear push rod moves toward the BN terminal (5) along its axial direction; When the upper section (2) of the linear push rod is in contact with the BN terminal (5) and the CN terminal (6) simultaneously, the error detection for the instrument transformer in distribution power grid with three-phase four-wire method is performed using the three-phase detection method.

5. According to claim 4, the said switching device based on the transformer error detecting wiring circuit is characterized in that the connections of the upper section (2), the middle section (3) and the lower section (4) are dismantlable.

6. According to claim 5, the said switching device based on the transformer error detecting wiring circuit is characterized in that the said upper section (2), the middle section (3) and the lower section (4) are connected by a buckle.

7. According to claim 4, the said switching device based on the transformer error detecting wiring circuit is characterized in that the rod wall of the said middle section (3) is engraved with radial insulation stripes.

8. According to claim 7, the said switching device based on the transformer error detecting wiring circuit is characterized in that the said radial insulation stripes are wavy or sawtooth.

9. According to claim 4, the said switching device based on the transformer error detecting wiring circuit is characterized in that a wireless communication module and a control chip are further installed on the driving motor (8), and the said driving motor (8) and the wireless communication module are respectively connected to the control chip, wherein:
The said wireless communication module is configured to receive wireless driving signals and transmit the wireless driving signals to the control chip;
The said control chip is used to receive the wireless driving signals transmitted by the wireless communication module, and to send forward driving signals or reverse driving signals to the driving motor (8);
The said driving motor (8) is used to receive forward rotation driving signals or reverse driving signals sent by the control chip, and to control the driving motor (8) to rotate forward or reverse.
